(19) United States
(12) Patent Application Publication
(10) Pub. No.: US 2026/0206200 A1
(43) Pub. Date: Jul. 16, 2026

(54) SEMICONDUCTOR STRUCTURE AND METHOD OF MANUFACTURING THE SAME

(71) Applicant: NANYA TECHNOLOGY CORPORATION, New Taipei City (TW)

(72) Inventors: Shih Min HUNG, New Taipei City (TW); Ying-Cheng CHUANG, New Taipei City (TW); Chung-Lin HUANG, New Taipei City (TW)

(21) Appl. No.: 19/026,159

(22) Filed: Jan. 16, 2025

(51) Int. Cl. H10B 12/00

(52) U.S. Cl. CPC H10B 12/05; H10B 12/33

(57) ABSTRACT

Embodiments of this disclosure provide a semiconductor structure. The semiconductor structure includes a capacitor over a substrate, a conductive cell on the capacitor, a vertical transistor on the conductive cell, a first oxide layer surrounding a lower portion of the vertical transistor, a first conductive layer surrounding a middle portion of the vertical transistor, and a second oxide layer surrounding an upper portion of the vertical transistor.

### BACKGROUND

### Field of Invention

The present disclosure relates to a semiconductor structure and a method of manufacturing the same for 4F² array.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A plurality of capacitors is formed over a substrate. A plurality of conductive cells are formed respectively on each of the plurality of capacitors. A sacrificial layer are deposited over the plurality of capacitors and covering a top surface of each of the plurality of conductive cells. A lithography process is performed to remove portions of the sacrificial layer to forming a plurality of first sacrificial pillars corresponding to the conductive cells. A first conductive layer surrounding a lower portion of the plurality of first sacrificial pillars is formed. A plurality of first spacers on two opposite sides of each of the plurality of first sacrificial pillars are deposited, and a plurality of second spacers respectively on outer sides of the plurality of first spacers are deposited. A first dielectric layer is deposited to fill a space between the adjacent two second spacers. The plurality of second spacers and the first conductive layer beneath the plurality of second spacers are etched to form a plurality of first openings. A second dielectric layer is filled in the plurality of first openings. The plurality of first sacrificial pillars are removed to form a plurality of second openings. A gate oxide layer is deposited in the plurality of second openings.

In some embodiments, an oxide material of the first dielectric layer is identical to an oxide material of the second dielectric layer.

In some embodiments, a lower portion of each of the plurality of capacitors is surrounded by a first insulating layer, and an upper portion of each of the plurality of capacitors is surrounded by a second insulating layer.

In some embodiments, after forming the conductive cell, the method further includes the following steps. An oxide layer, a first coating layer, an anti-reflection layer, and a first photoresist layer containing a first channel hole pattern are deposited on the plurality of conductive cells and the second insulating layer from bottom to top. The lithography process is performed to remove portions of the oxide layer to expose a top surface of the plurality of conductive cells.

In some embodiments, the forming the first conductive layer surrounding the lower portion of each of the plurality of first sacrificial pillars includes the following steps. A first conductive layer is deposited over the second insulating layer until completely covering the plurality of first sacrificial pillars. An upper portion of the first conductive layer is etched until exposing an upper portion of each of the plurality of first sacrificial pillars.

In some embodiments, after forming the first conductive layer, the method further includes the following steps. An underlayer coating layer is deposited on the first conductive layer and the plurality of first sacrificial pillars, wherein a top surface of the underlayer coating layer is higher than a top surface of each of the plurality of first sacrificial pillars. A second coating layer on the underlayer coating layer is deposited. A mask layer is formed on the second coating layer. The lithography process is performed on the mask layer and the underlayer coating layer until exposing a top surface of the first conductive layer to form a plurality of second sacrificial pillars respectively on the plurality of first sacrificial pillars.

In some embodiments, after forming the plurality of second sacrificial pillars respectively on the plurality of first sacrificial pillars, the method further includes the following steps. The plurality of first spacers are respectively deposited on two opposite sides of the plurality of first sacrificial pillars and the plurality of second sacrificial pillars. The plurality of second spacers are respectively deposited on the outer sides of the plurality of first spacers. A planarization process is performed on the plurality of second sacrificial pillars, the plurality of first spacers, and the plurality of second spacers until exposing the top surface of each of the plurality of first sacrificial pillars.

In some embodiments, before the planarization process, each of the plurality of first sacrificial pillars has a first height, and after the planarization process, each of the plurality of the first sacrificial pillars has a second height, and the second height is shorter than the first height.

In some embodiments, a thickness of each of the plurality of second spacers is greater than a thickness of each of the plurality of first spacers.

In some embodiments, wherein after depositing the gate oxide layer in the second openings, the method further includes the following steps. A gate conductive layer is formed in the gate oxide layer. A second conductive layer is deposited on the gate conductive layer, the gate oxide layer, the first dielectric layer, and the second dielectric layer. A third conductive layer is deposited on the second conductive layer.

Embodiments of this disclosure provide a semiconductor structure. The semiconductor structure includes a capacitor over a substrate, a conductive cell on the capacitor, a vertical transistor on the conductive cell, a first oxide layer surrounding a lower portion of the vertical transistor, a first conductive layer surrounding a middle portion of the vertical transistor, and a second oxide layer surrounding an upper portion of the vertical transistor.

In some embodiments, a bottom surface of the first conductive layer is in contact with a top surface of the first oxide layer.

In some embodiments, the semiconductor structure further includes a first dielectric layer on the first conductive layer and a second dielectric layer surrounding the first conductive layer and the second oxide layer.

In some embodiments, an oxide material of the first dielectric layer is identical to an oxide material of the second dielectric layer.

In some embodiments, an oxide material of the second dielectric layer is identical to an oxide material of the second oxide layer.

In some embodiments, a lower portion of the capacitor is surrounded by a first insulating layer, and an upper portion of the capacitor is surrounded by a second insulating layer.

In some embodiments, a width of the first conductive layer is identical a width of an upper portion of the capacitor.

In some embodiments, the vertical transistor includes a gate conductive layer on the conductive cell and a gate oxide layer on the conductive cell and surrounding the gate conductive layer, wherein a sidewall of the gate oxide layer is substantially aligned with a sidewall of the conductive cell.

In some embodiments, the semiconductor structure further includes a landing pad on the vertical transistor. The landing pad includes a second conductive layer on the vertical transistor and a third conductive layer on the second conductive layer.

In some embodiments, a pad width of the landing pad is greater than a transistor width of the vertical transistor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIG. 1 is a top view of a method of manufacturing a semiconductor structure during forming a plurality of first sacrificial pillars according to some embodiments of this disclosure,

FIGS. 2-6 are cross-section views of a method of manufacturing a semiconductor structure during forming a plurality of first sacrificial pillars based on A-A′ line of FIG. 1 according to some embodiments of this disclosure,

FIG. 7 is a top view of a method of manufacturing a semiconductor structure during forming a plurality of second sacrificial pillars according to some embodiments of this disclosure,

FIGS. 8-11 are cross-section views of a method of manufacturing a semiconductor structure during forming a plurality of second sacrificial pillars based on A-A′ line of FIG. 7 according to some embodiments of this disclosure,

FIG. 12 is a top view of a method of manufacturing a semiconductor structure during forming a plurality of first spacers and a plurality of second spacers according to some embodiments of this disclosure,

FIGS. 13-15 are cross-section views of a method of manufacturing a semiconductor structure during forming a plurality of first spacers and a plurality of second spacers based on A-A′ line of FIG. 12 according to some embodiments of this disclosure,

FIG. 16 is a top view of a method of manufacturing a semiconductor structure during forming a plurality of vertical transistors according to some embodiments of this disclosure, and

FIGS. 17-22 are cross-section views of a method of manufacturing a semiconductor structure during forming a plurality of vertical transistors based on A-A′ line of FIG. 16 according to some embodiments of this disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

As the improvement of the semiconductor industry, a novel 4F² DRAM technology increases the number of dies produced on the same area of a wafer through changing a DRAM design without increasing the development cost and improving yield. For improving the process of producing the 4F² chip, a method of manufacturing a semiconductor structure is provided.

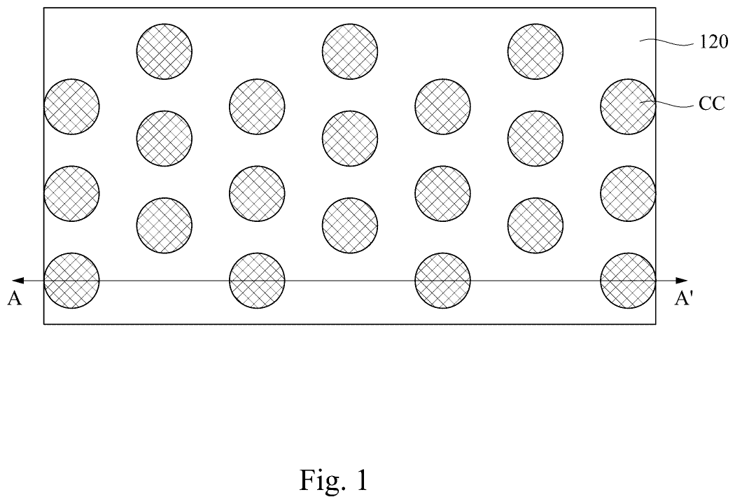

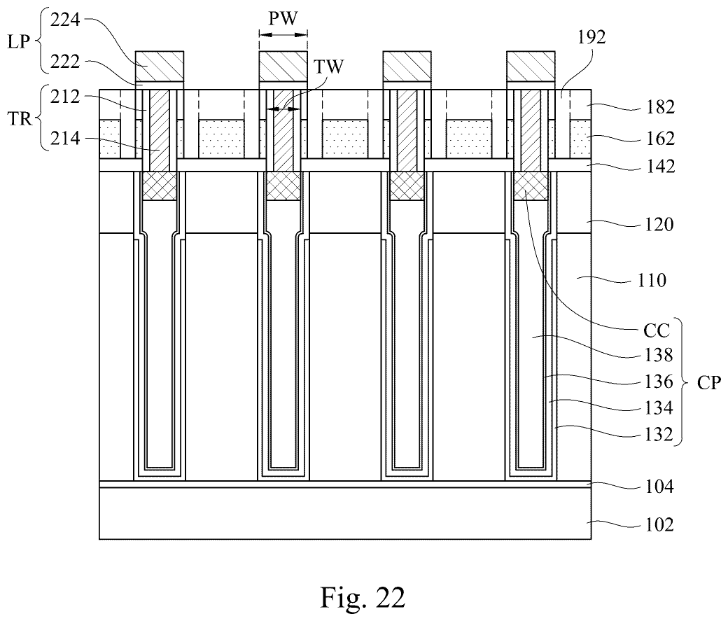

It should be noted that when the following figures, such as FIGS. 1 to 22, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 22) to completely form the semiconductor structure 100. Therefore, the present disclosure may briefly illustrate some of these additional operations or steps. Further, unless otherwise stated, the same explanations discussed for the following figures, such as FIGS. 1 to 22, apply directly to the other figures.

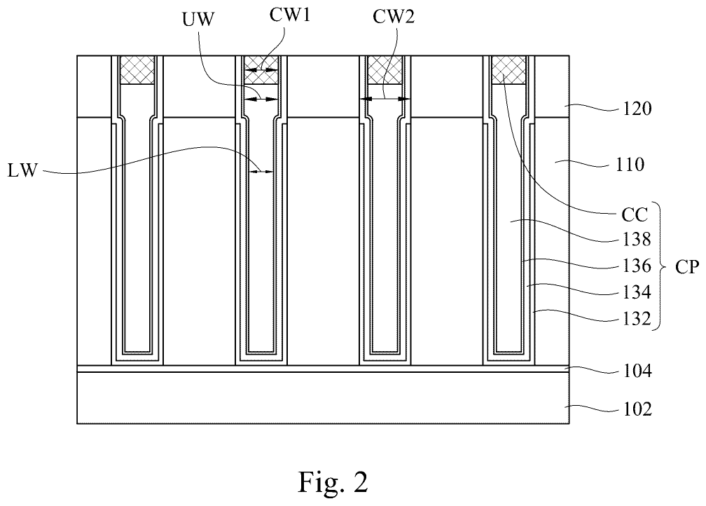

Please refer to FIGS. 1-6. FIG. 1 is a top view of a method of manufacturing a semiconductor structure during forming a plurality of first sacrificial pillars according to some embodiments of this disclosure, and FIGS. 2-6 are cross-section views of a method of manufacturing a semiconductor structure during forming a plurality of first sacrificial pillars based on A-A′ line of FIG. 1 according to some embodiments of this disclosure.

In FIG. 2, a plurality of capacitors CP are formed over a substrate 102. In some embodiments, the substrate 102 includes silicon, such as crystalline silicon, polycrystalline silicon, or amorphous silicon. The substrate 102 may include an elemental semiconductor, such as germanium. In some embodiments, the substrate 102 may include alloy semiconductors, such as silicon germanium, silicon germanium carbide, gallium indium phosphide, or other suitable materials. In some embodiments, the substrate 102 may include compound semiconductors, such as silicon carbide (SiC), gallium arsenide (GaAs), indium phosphide (InP), indium arsenide (InAs), or other suitable materials. In some embodiments, the substrate 102 may optionally have a semiconductor-on-insulator (SOI) structure.

In some embodiments, an active device layer 104 is formed on the substrate. In some embodiments, the active device layer 104 includes tungsten (W), copper (Cu), or other suitable materials.

Next, a first insulating layer 110 is deposited over the substrate 102, and a second insulating layer 120 is formed on the first insulating layer 110. In some embodiments, the first insulating layer 110 includes tetraethoxysilane (TEOS). In some embodiments, the first insulating layer 110 is deposited by chemical vapor deposition (CVD), physical vapor deposition (PVD), or other suitable deposition process. In some embodiments, the second insulating layer 120 includes nitride, such as SiN. In some embodiments, the second insulating layer 120 is deposited by CVD, PVD, or other suitable deposition process. In some embodiments, a thickness of the first insulating layer 110 is greater than a thickness of the second insulating layer 120.

Subsequently, a plurality of capacitor openings (not shown) are formed in the second insulating layer 120 and the first insulating layer 110 until exposing a top surface of each of the active device layer 104. Subsequently, a bottom capacitor plate 132 is deposited on an inner surface of each of the capacitor openings in the first insulating layer 110 without being deposited on an inner surface of each of the capacitor openings in the second insulating layer 120. In some embodiments, the bottom capacitor plate 132 includes TiN or other suitable conductive materials.

Next, a capacitor oxide layer 134 is deposited on the bottom capacitor plate 132 and an inner surface of each of the capacitor openings in the second insulating layer 120. A capacitor dielectric layer 136 is deposited on the capacitor oxide layer 134. In some embodiments, the capacitor oxide layer 134 includes oxide, and the capacitor dielectric layer 136 includes oxide or other dielectric materials. In some embodiments, top surfaces of the capacitor oxide layer 134, the capacitor dielectric layer 136 and the second insulating layer 120 are coplanar. A top capacitor plate 138 is deposited on the capacitor dielectric layer 136, and a top surface of the top capacitor plate 138 is lower than the top surface of the second insulating layer 120. In some embodiments, the top capacitor plate 138 includes TiN or other suitable conductive materials. In some embodiments, an upper width of the top capacitor plate 138 in the second insulating layer 120 is greater than a lower width of the top capacitor plate 138 in the first insulating layer 110.

Further, a plurality of conductive cells CC are respectively formed on the top capacitor plate 138, a sidewall of each of the conductive cells CC is surrounded by the capacitor dielectric layer 136. In some embodiments, a top surface of each of the conductive cells CC, the top surface of the top surfaces of the capacitor oxide layer 134, the capacitor dielectric layer 136 and the second insulating layer 120 are coplanar. In some embodiments, each of the conductive cells CC includes indium tin oxides (ITO). In some embodiments, a cell width of each of the conductive cells CC is identical to the upper width of the top capacitor plate 138 in the second insulating layer 120. Consequently, each of the capacitors CP is formed after forming the conductive cells CC. In addition, each of the capacitors CP in the second insulting layer 120 has a capacitor width CW2.

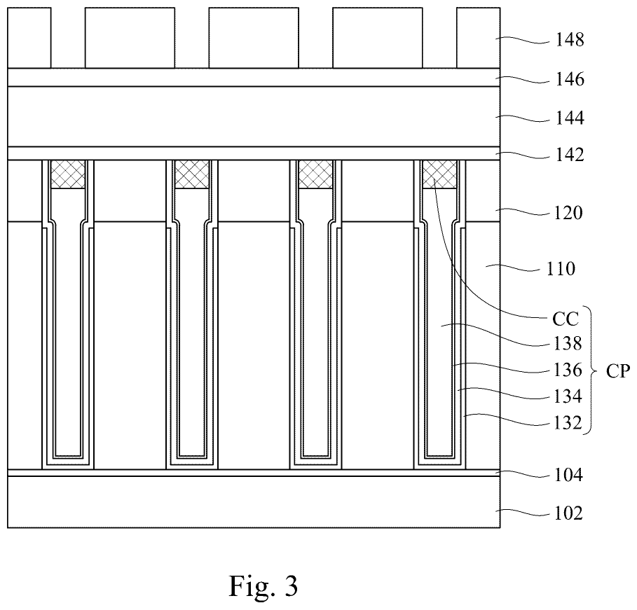

In FIG. 3, an oxide layer 142 is deposited on the conductive cells CC and the second insulating layer 120, a first coating layer 144 is deposited on the oxide layer 142, an anti-reflection layer 146 is deposited on the first coating layer 144, and a first photoresist layer 148 containing a first channel hole pattern is deposited on the anti-reflection layer 146. In some embodiments, the oxide layer 142 includes oxide, such as SiO₂. In some embodiments, the first coating layer 144 includes carbon. In some embodiments, the first channel hole pattern is related to positions of the conductive cells CC. Specifically, the first photoresist layer 148 containing the first channel hole pattern exposes positions corresponding to the conductive cells CC, respectively.

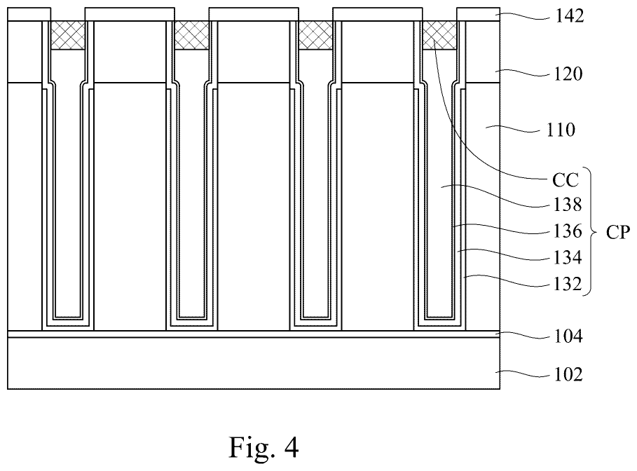

In FIG. 4, a lithography process is performed on the first photoresist layer 148 to expose each of the top surface of the conductive cells CC. Then, the first photoresist layer 148, the anti-reflection layer 146, and the first coating layer 144 (in FIG. 3) are removed by a removing process. The removing process includes an etching process, such as a dry etching process or a wet etching process, a chemical mechanical polishing (CMP) process or a combination thereof.

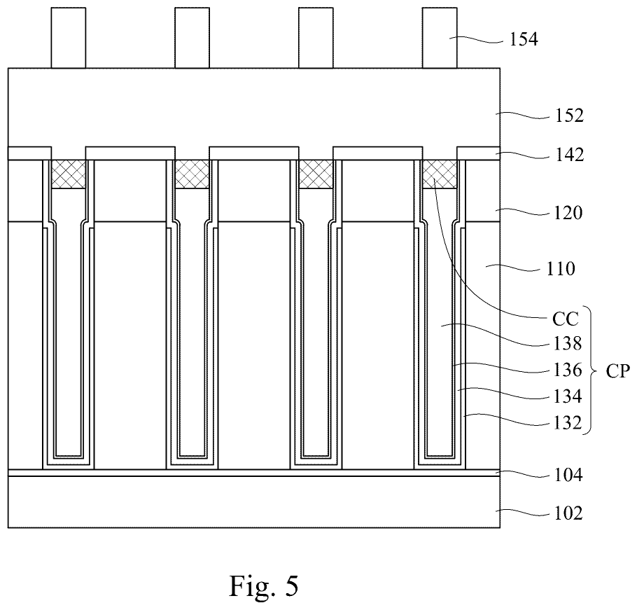

In FIG. 5, a sacrificial layer 152 is deposited on the conductive cells CC and the oxide layer 142 to cover the top surface of each of the conductive cells CC. In some embodiments, the sacrificial layer 152 includes Si, such as polysilicon. Then, a second photoresist layer 154 containing a second channel hole pattern is formed on the sacrificial layer 152. Moreover, the second photoresist layer 154 containing the second channel hole pattern covers positions corresponding to the conductive cells CC, respectively.

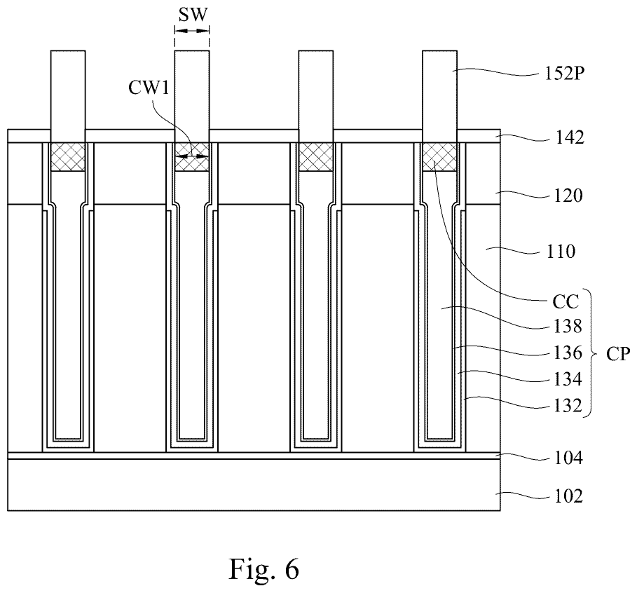

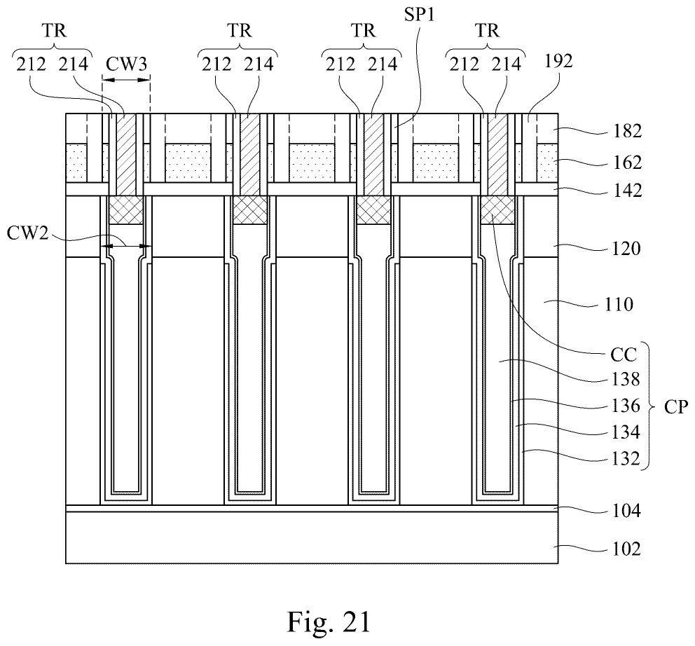

In FIG. 6, the lithography process is performed on the second photoresist layer 154 containing the second channel hole pattern and the sacrificial layer 152 (in FIG. 5) to remove portions of the sacrificial layer 152 exposed by the sacrificial layer 152, so as to form a plurality of first sacrificial pillars 152P corresponding to the conductive cells CC, respectively. In some embodiments, a pillar width SW of each of the first sacrificial pillars 152P is identical to the cell width CW1 of each of the conductive cells CC. In some embodiments, the lithography process includes electron beam lithography and double pitch splitting lithography. Moreover, the sacrificial layer 152 is configured to keep a space where a gate oxide layer (such as FIG. 21) formed, and avoid damage to the space where the gate oxide layer (such as the gate oxide layer 212) formed during various processes, such as an etching process.

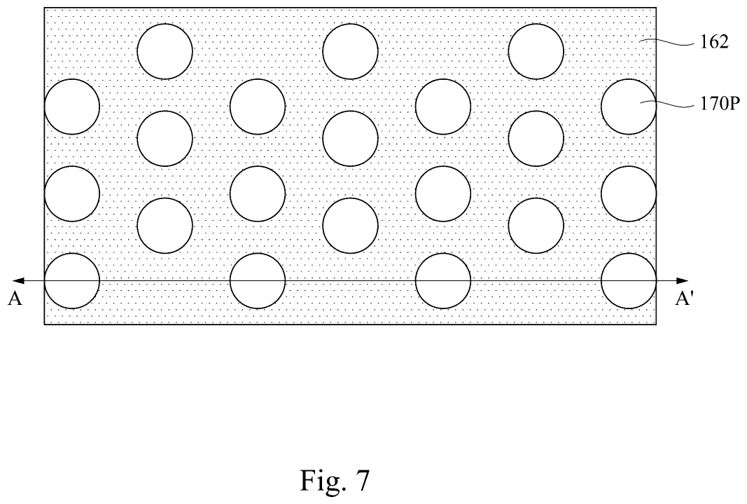

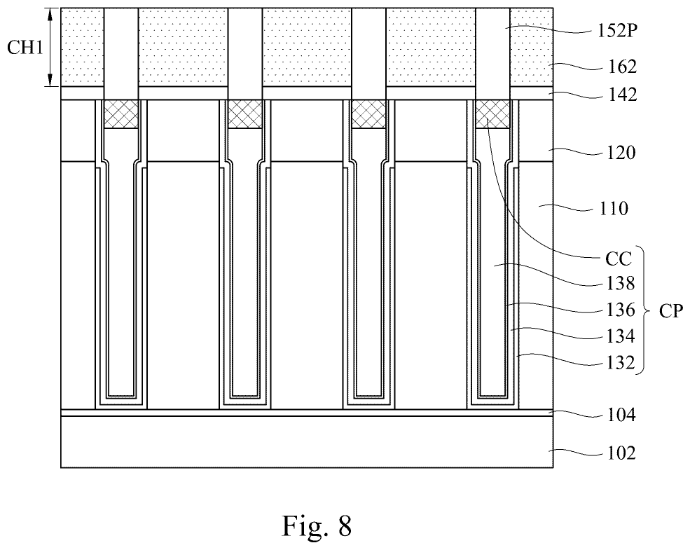

Please refer to FIGS. 7-11. FIG. 7 is a top view of a method of manufacturing a semiconductor structure during forming a plurality of second sacrificial pillars according to some embodiments of this disclosure, and FIGS. 8-11 are cross-section views of a method of manufacturing a semiconductor structure during forming a plurality of second sacrificial pillars based on A-A′ line of FIG. 7 according to some embodiments of this disclosure.

In FIG. 8, a first conductive layer 162 is deposited on the oxide layer 142 until completely covering the first sacrificial pillars 152P. In some embodiments, a planarization process, such as CMP, is performed on the first conductive layer 162 to make a top surface of the first conductive layer 162 and a top surface of each of the first sacrificial pillars 152P are coplanar. In some embodiments, a material of the first conductive layer 162 includes metal, such as W, Cu, or other suitable metal. In some embodiments, the first conductive layer 162 has a first conductive height CH1.

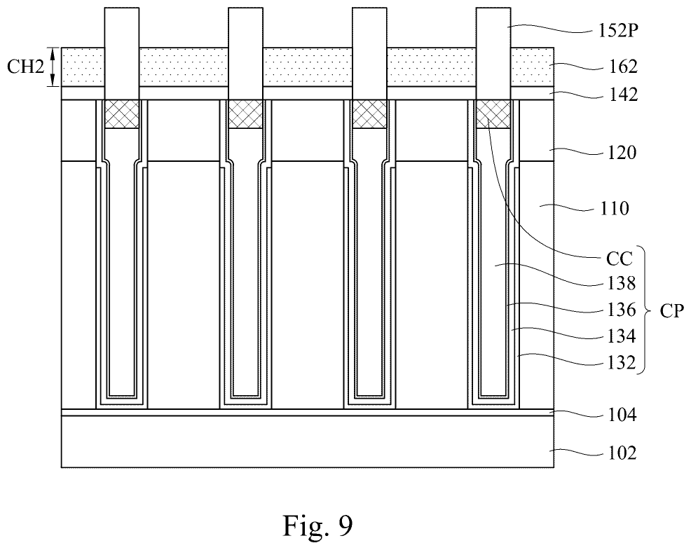

In FIG. 9, an upper portion of the first conductive layer 162 is etched until exposing an upper portion of each of the first sacrificial pillars 152P, so as to form the first conductive layer 162 on the oxide layer 142 and surrounding a lower portion of each of the first sacrificial pillars 152P. In some embodiments, the upper portion of the first conductive layer 162 is etched by an etching back process. In some embodiments, after etching, the first conductive layer 162 is shortened from the first conductive height CH1 (in FIG. 9) to a second conductive height CH2. In some embodiments, the shortened first conductive layer 162 is a word line.

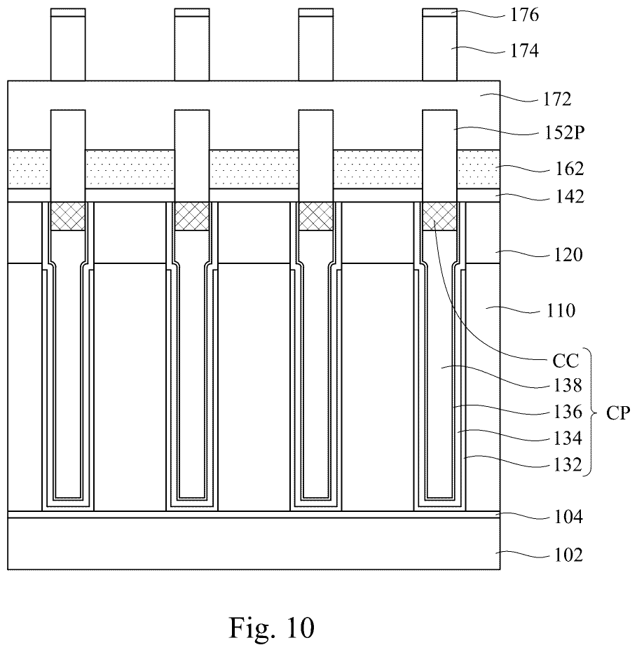

In FIG. 10, an underlayer coating layer 172 is deposited on the first conductive layer 162 and the first sacrificial pillars 152P. Moreover, a top surface of the underlayer coating layer 172 is higher than the top surface of each of the plurality of first sacrificial pillars 152P. Subsequently, a second coating layer 174 is deposited on the underlayer coating layer 172. Then, a mask layer 176 containing the second channel hole pattern is formed on the underlayer coating layer 172. Specifically, the mask layer 176 containing the second channel hole pattern covers positions corresponding to the conductive cells CC, respectively.

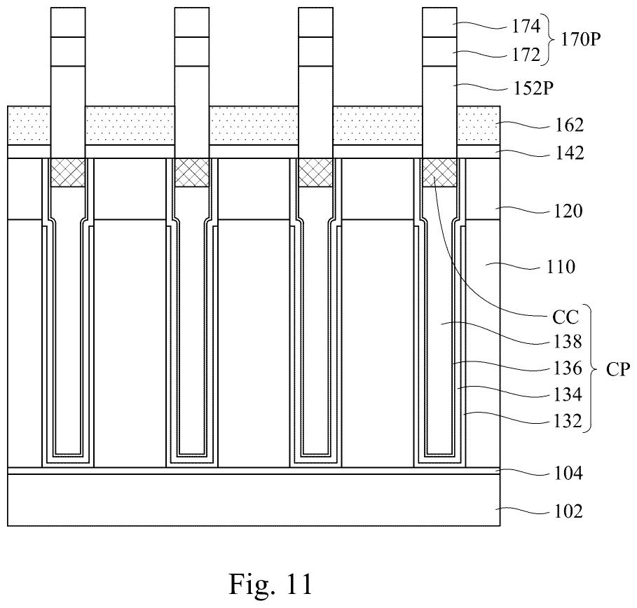

In FIG. 11, the lithography process is performed on the mask layer 176 (in FIG. 10), the second coating layer 174, and the underlayer coating layer 172 until exposing a top surface of the first conductive layer 162 to form a plurality of second sacrificial pillars 170P respectively on the plurality of first sacrificial pillars 152P.

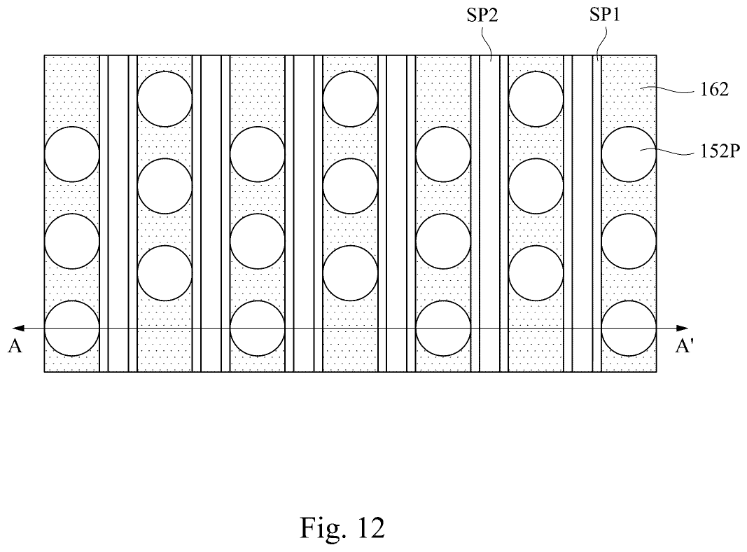

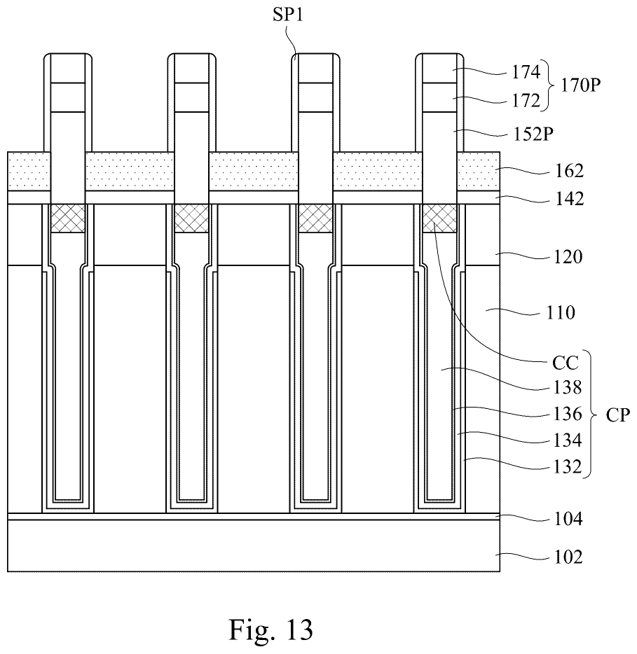

Please refer to FIGS. 12-15. FIG. 12 is a top view of a method of manufacturing a semiconductor structure during forming a plurality of first spacers and a plurality of second spacers according to some embodiments of this disclosure, and FIGS. 13-15 are cross-section views of a method of manufacturing a semiconductor structure during forming a plurality of first spacers and a plurality of second spacers based on A-A′ line of FIG. 12 according to some embodiments of this disclosure.

In FIG. 13, a plurality of first spacers SP1 are deposited respectively on two opposite sides of each of the first sacrificial pillars 152P and each of the second sacrificial pillars 170P. In some embodiments, a material of each of the first spacers SP1 includes oxide, such as SiO₂. In some embodiments, the planarization process, such as an etching process or CMP, is performed on the first spacers SP1 to make a top surface of each of the first spacers SP1 and a top surface of each of the second sacrificial pillars 170P coplanar.

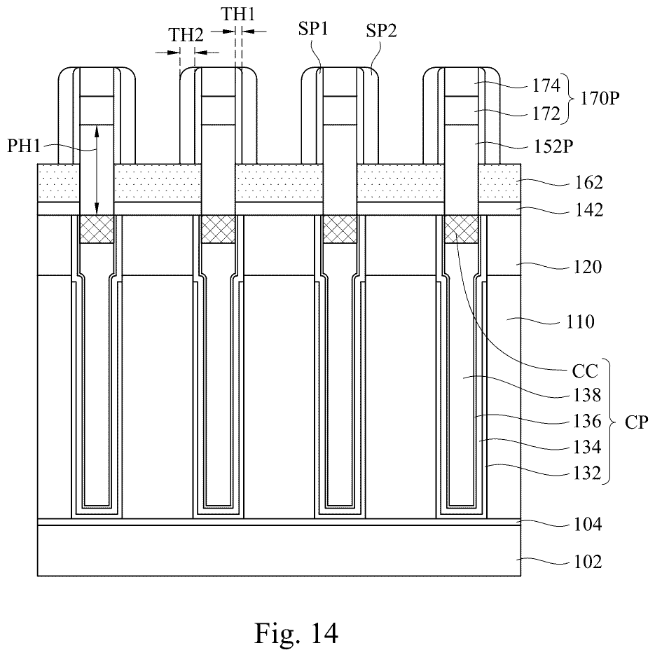

In FIG. 14, a plurality of second spacers SP2 is deposited respectively on an outer side of each of the first spacers SP1. In some embodiment, a material of each of the second spacers SP2 includes nitride, such as SiN. In some embodiments, the planarization process, such as an etching process or CMP, is performed on the second spacers SP2 to make a top surface of each of the second spacers SP2, the top surface of each of the first spacers SP1, and the top surface of each of the second sacrificial pillars 170P coplanar. In some embodiments, each of the first spacers SP1 has a first thickness TH1, each of the second spacers SP2 has a second thickness TH2, and the second thickness TH2 is greater than the first thickness TH1. Moreover, the first spacers SP1 and the second spacers SP2 is configured to protect the space for a vertical transistor (such as FIG. 22) connecting the first conductive layer 162 (or called the word line).

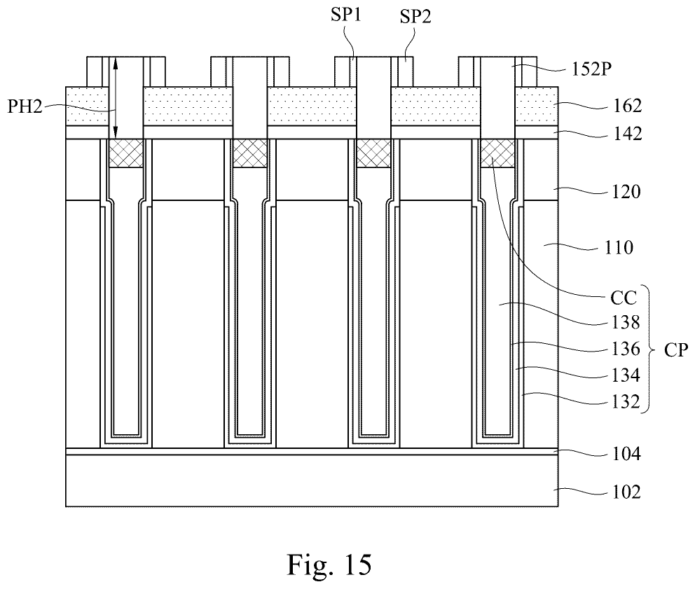

In FIG. 15, the planarization process, such as CMP, is performed on the second sacrificial pillars 170P, the first spacers SP1, and the second spacers SP2 until exposing the top surface of each of the first sacrificial pillars 152P. In other words, the second sacrificial pillars 170P (in FIG. 14) are removed after the planarization process. In some embodiments, before the planarization process each of the plurality of first sacrificial pillars 152P has a first height PH1 (in FIG. 14), and after the planarization process, each of the plurality of the first sacrificial pillars 152P is shortened from the first height HP1 to a second height PH2.

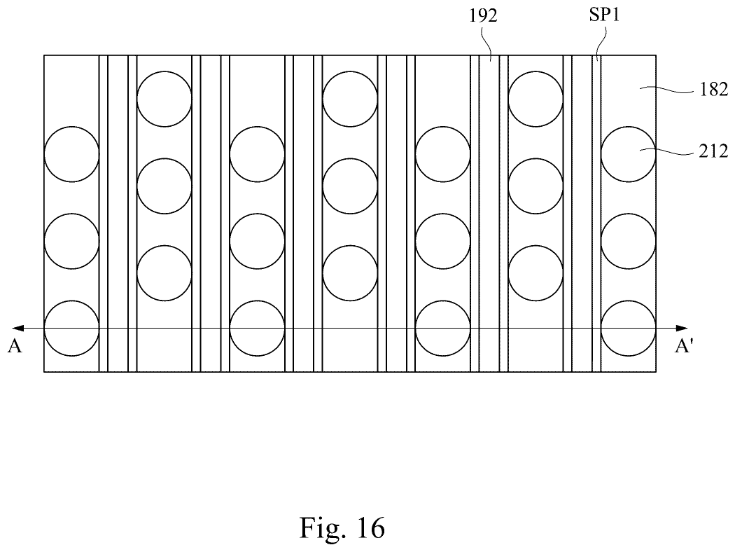

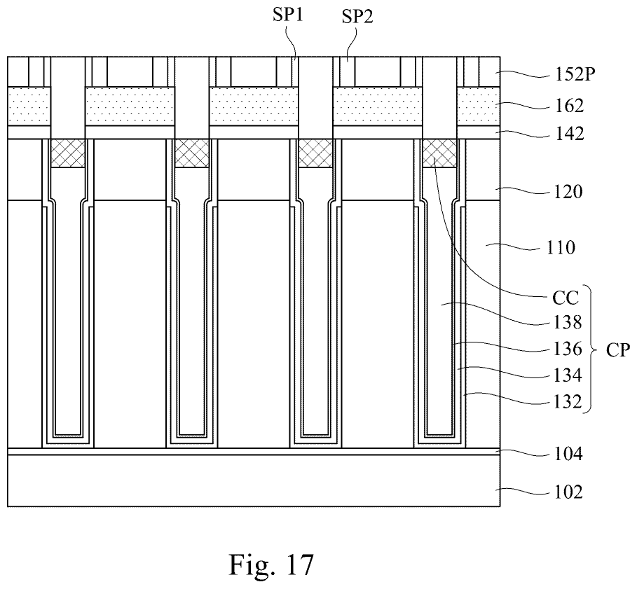

Please refer to FIGS. 16-22. FIG. 16 is a top view of a method of manufacturing a semiconductor structure during forming a plurality of vertical transistors according to some embodiments of this disclosure, and FIGS. 17-22 are cross-section views of a method of manufacturing a semiconductor structure during forming a plurality of vertical transistors based on A-A′ line of FIG. 16 according to some embodiments of this disclosure.

In FIG. 17, a space (in FIG. 15) between the adjacent two second spacers is filled with a first dielectric layer 182. In some embodiments, the planarization process, such as CMP, is performed on the first dielectric layer 182 until a top surface of the first dielectric layer 182, the top surface of each of the second spacers SP1, and the top surface of each of the first spacers SP1 being coplanar. In some embodiments, a material of the first dielectric layer 182 includes oxide.

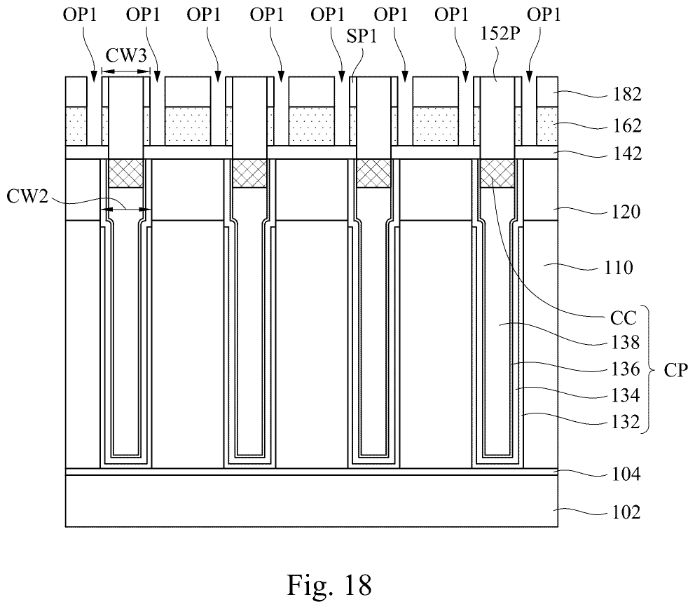

In FIG. 18, the second spacers SP2 and the first conductive layer 162 beneath the respective second spacers SP2 are etched to form a plurality of first openings OP1. Specifically, the second spacers SP2 are first etched by a dry etching process, electron beam lithography, or double pitch splitting lithography, and then the first conductive layer 162 beneath the respective second spacers SP2 is etched by the dry etching process. In some embodiments, an etching selectivity of each of the second spacers SP2 is greater than an etching selectivity of each of the first spacers SP1. Therefore, each of the first spacers SP1 is served as a protection layer to prevent the first conductive layer 162 beneath the respective first spacers SP1 from being etched. In some embodiments, the etching selectivity of each of the second spacers SP2 is greater than an etching selectivity of each of the first sacrificial pillars 152P. Therefore, the first sacrificial pillars 152P are not etched during etching the second spacers SP2 and the first conductive layer 162 beneath the respective second spacers SP2. In some embodiments, the first conductive layer 162 surrounding each of the first sacrificial pillars 152P has a conductive width CW3, and the capacitor width CW2 of each of the capacitors CP in the second insulating layer 120 is identical to the conductive width CW3 the first conductive layer 162 surrounding each of the first sacrificial pillars 152P.

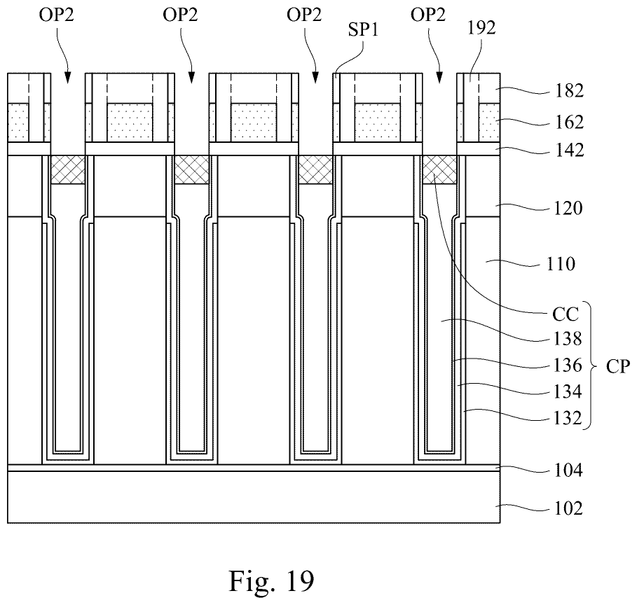

In FIG. 19, a second dielectric layer 192 is filled in the first openings OP2. In some embodiments, a material of the second dielectric layer 192 includes oxide. In some embodiments, the material of the first dielectric layer 182 is identical to the material of the second dielectric layer 192. That is, the oxide material of the first dielectric layer 182 is identical to the oxide material of the second dielectric layer 192. Subsequently, the first sacrificial pillars 152P (in FIG. 18) are removed to form a plurality of second openings OP2. Via disposing the second spacer SP2 on the outside of the first spacer SP1 and taking advantage of the difference in the etching selectivities between the first spacer SP1 and the second spacer SP2, a given area where the vertical transistor TR formed is protected. In this way, on the one hand, the density of cells can be increased in the same given area, and on the other hand, the vertical transistor TR can be formed accurately corresponding to each of the conductive cells CC.

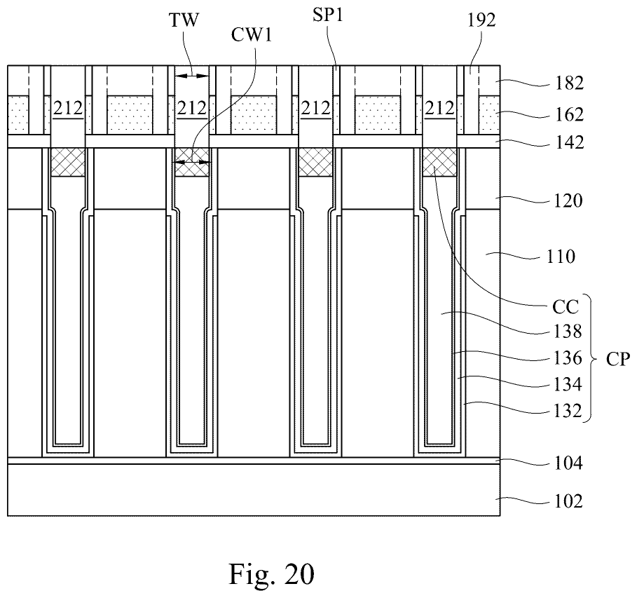

In FIG. 20, a gate oxide layer 212 is deposited in each of the second openings OP2. In some embodiments, the gate oxide layer 212 has a transistor width TW, and the transistor width TW of the gate oxide layer 212 is identical to the cell width CW1 of each of the conductive cells CC.

In FIG. 21, a conductive opening (not shown) is formed in the gate oxide layer 212. Subsequently, a gate conductive layer 214 is formed in the conductive opening to form a vertical transistor TR. In addition, a sidewall of the gate conductive layer 214 is surrounded by the gate oxide layer 212, and a bottom surface of the gate conductive layer 214 is in contact with the top surface of each of the conductive cells CC. In some embodiments, the gate conductive layer 214 includes indium gallium zinc oxide (IGZO).

In FIG. 22, a plurality of landing pads LP are formed on the vertical transistor TR, respectively. Specifically, a second conductive layer 222 is deposited on the vertical transistors TR, and a third conductive layer 224 is deposited on the second conductive layer. Further, a mask (not shown) is formed on the third conductive layer 224 covering positions corresponding the vertical transistor TR, the first spacers SP1 surrounding an upper portion of the vertical transistor TR, and the conductive layer 162 surrounding an lower portion of the vertical transistor TR, and the lithography process is performed on the mask and the third conductive layer 224 to remove the third conductive layer 224 and the second conductive layer 222 exposed by the mask until the top surfaces the first dielectric layer 182 and the second dielectric layer 192.

Embodiments of this disclosure also provide a semiconductor structure, as shown in FIGS. 21 and 22. The semiconductor structure includes a capacitor CP over a substrate, a conductive cell CC on the capacitor CP, a vertical transistor TR on the conductive cell CC, a first oxide layer 142 surrounding a lower portion of the vertical transistor TR, a first conductive layer 162 surrounding a middle portion of the vertical transistor TR, and a second oxide layer SP1 surrounding an upper portion of the vertical transistor TR. In some embodiments, a bottom surface of the first conductive layer 162 is in contact with a top surface of the first oxide layer 142.

The capacitor CP includes a top capacitor plate 138, a capacitor dielectric layer 136 surrounding the top capacitor plate 138, a capacitor oxide layer 134 surrounding the capacitor dielectric layer 136, and a bottom capacitor plate 132 surrounding a lower portion of the capacitor oxide layer 134. Moreover, the semiconductor structure 100 further includes a first insulating layer 110 surrounding a lower portion of the capacitor CP and a second insulating layer 120 surrounding an upper portion of the capacitor CP. In some embodiments, a width CW3 of the first conductive layer 162 is identical a width CW2 of the upper portion of the capacitor CP in the second insulating layer 120.

In some embodiments, the semiconductor structure 100 further includes a first dielectric layer 182 on the first conductive layer 162 and a second dielectric layer 192 surrounding the first conductive layer 162 and the second oxide layer SP1. In some embodiments, an oxide material of the first dielectric layer 182 is identical to an oxide material of the second dielectric layer 192. In some embodiments, an oxide material of the second dielectric layer 192 is identical to an oxide material of the second oxide layer SP2.

The vertical transistor TR includes a gate conductive layer 214 on the conductive cell CC and a gate oxide layer 212 on the conductive cell CC and surrounding the gate conductive layer 214. Moreover, a sidewall of the gate oxide layer 212 is substantially aligned with a sidewall of the conductive cell CC. In some embodiments, the transistor width TW of the vertical transistor TR is identical to the cell width CW1 of each of the conductive cell CC. In some embodiments, a bottom surface of the vertical transistor TR is in contact with a top surface of the conductive cell CC.

The semiconductor structure 100 further includes a landing pad LP on the vertical transistor. The landing pad LP includes a second conductive layer 222 on the vertical transistor TR and a third conductive layer 224 on the second conductive layer 222. In some embodiments, a pad width PW of the landing pad LP is greater than a transistor width TW of the vertical transistor TR. In some embodiments, a top surface of the vertical transistor TR is in contact with a bottom surface of the second conductive layer 222.

Through the semiconductor structure and the method of manufacturing the same, while increasing the cell density in a given area of a chip, a resolution between the conductive cells can be taken into consideration so that the oxide gate layer for connecting the first conductive layer (or called the word line) can accurately formed corresponding to the conductive cells, thereby increasing the 4F² DRAM yield.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
forming a plurality of capacitors over a substrate;
forming a plurality of conductive cells respectively on each of the plurality of capacitors;
depositing a sacrificial layer over the plurality of capacitors and covering a top surface of each of the plurality of conductive cells;
performing a lithography process to remove portions of the sacrificial layer to forming a plurality of first sacrificial pillars corresponding to the conductive cells;
forming a first conductive layer surrounding a lower portion of the plurality of first sacrificial pillars;
depositing a plurality of first spacers on two opposite sides of each of the plurality of first sacrificial pillars and depositing a plurality of second spacers respectively on outer sides of the plurality of first spacers;
depositing a first dielectric layer to fill a space between the adjacent two second spacers;
etching the plurality of second spacers and the first conductive layer beneath the plurality of second spacers to form a plurality of first openings;
filling a second dielectric layer in the plurality of first openings;
removing the plurality of first sacrificial pillars to form a plurality of second openings; and
depositing a gate oxide layer in the plurality of second openings.

2. The method of claim 1, wherein an oxide material of the first dielectric layer is identical to an oxide material of the second dielectric layer.

3. The method of claim 1, wherein a lower portion of each of the plurality of capacitors is surrounded by a first insulating layer, and an upper portion of each of the plurality of capacitors is surrounded by a second insulating layer.

4. The method of claim 3, wherein after forming the plurality of conductive cells, the method further comprises:
depositing an oxide layer, a first coating layer, an anti-reflection layer, and a first photoresist layer containing a first channel hole pattern on the plurality of conductive cells and the second insulating layer from bottom to top; and
performing the lithography process to remove portions of the oxide layer to expose a top surface of the plurality of conductive cells.

5. The method of claim 3, wherein the forming the first conductive layer surrounding the lower portion of each of the plurality of first sacrificial pillars comprises:
depositing the first conductive layer over the second insulating layer until completely covering the plurality of first sacrificial pillars; and
etching an upper portion of the first conductive layer until exposing an upper portion of each of the plurality of first sacrificial pillars.

6. The method of claim 5, wherein after forming the first conductive layer, the method further comprises:
depositing an underlayer coating layer on the first conductive layer and the plurality of first sacrificial pillars, wherein a top surface of the underlayer coating layer is higher than a top surface of each of the plurality of first sacrificial pillars;
depositing a second coating layer on the underlayer coating layer;
forming a mask layer on the second coating layer; and
performing the lithography process on the mask layer and the underlayer coating layer until exposing a top surface of the first conductive layer to form a plurality of second sacrificial pillars respectively on the plurality of first sacrificial pillars.

7. The method of claim 6, wherein after forming the plurality of second sacrificial pillars respectively on the plurality of first sacrificial pillars, the method further comprises:
depositing the plurality of first spacers respectively on two opposite sides of the plurality of first sacrificial pillars and the plurality of second sacrificial pillars;
depositing the plurality of second spacers respectively on the outer sides of the plurality of first spacers; and
performing a planarization process on the plurality of second sacrificial pillars, the plurality of first spacers, and the plurality of second spacers until exposing the top surface of each of the plurality of first sacrificial pillars.

8. The method of claim 7, wherein
before the planarization process, each of the plurality of first sacrificial pillars has a first height, and
after the planarization process, each of the plurality of the first sacrificial pillars has a second height, and the second height is shorter than the first height.

9. The method of claim 7, a thickness of each of the plurality of second spacers is greater than a thickness of each of the plurality of first spacers.

10. The method of claim 1, wherein after depositing the gate oxide layer in the second openings, the method further comprises:
forming a gate conductive layer in the gate oxide layer;
depositing a second conductive layer on the gate conductive layer, the gate oxide layer, the first dielectric layer, and the second dielectric layer; and
depositing a third conductive layer on the second conductive layer.

11. A semiconductor structure, comprising:
a capacitor over a substrate;
a conductive cell on the capacitor;
a vertical transistor on the conductive cell;
a first oxide layer surrounding a lower portion of the vertical transistor;
a first conductive layer surrounding a middle portion of the vertical transistor; and
a second oxide layer surrounding an upper portion of the vertical transistor.

12. The semiconductor structure of claim 11, wherein a bottom surface of the first conductive layer is in contact with a top surface of the first oxide layer.

13. The semiconductor structure of claim 11, further comprising:
a first dielectric layer on the first conductive layer; and
a second dielectric layer surrounding the first conductive layer and the second oxide layer.

14. The semiconductor structure of claim 13, wherein an oxide material of the first dielectric layer is identical to an oxide material of the second dielectric layer.

15. The semiconductor structure of claim 13, wherein an oxide material of the second dielectric layer is identical to an oxide material of the second oxide layer.

16. The semiconductor structure of claim 11, wherein a lower portion of the capacitor is surrounded by a first insulating layer, and an upper portion of the capacitor is surrounded by a second insulating layer.

17. The semiconductor structure of claim 11, wherein a width of the first conductive layer is identical a width of an upper portion of the capacitor.

18. The semiconductor structure of claim 11, wherein the vertical transistor comprises:
a gate conductive layer on the conductive cell; and
a gate oxide layer on the conductive cell and surrounding the gate conductive layer,
wherein a sidewall of the gate oxide layer is substantially aligned with a sidewall of the conductive cell.

19. The semiconductor structure of claim 11, further comprising:
a landing pad on the vertical transistor, wherein the landing pad comprises:
a second conductive layer on the vertical transistor; and
a third conductive layer on the second conductive layer.

20. The semiconductor structure of claim 19, wherein a pad width of the landing pad is greater than a transistor width of the vertical transistor.
